(19) United States
(12) Patent Application Publication
(10) Pub. No.: US 2013/0181752 A1
(43) Pub. Date: Jul. 18, 2013

(54) TIMING CONTROL CIRCUIT FOR SWITCHING CAPACITOR DYNAMIC SWITCH AND CONTROL METHOD THEREOF

(71) Applicant: INDUSTRIAL TECHNOLOGY RESEARCH INSTITUTE, Hsinchu (TW)

(72) Inventors: Ke-Horng Chen, Hsinchu (TW); Tzu-Chi Huang, Hsinchu (TW); Yao-Yi Yang, Changhua County (TW)

(73) Assignee: INDUSTRIAL TECHNOLOGY RESEARCH INSTITUTE, Hsinchu (TW)

(21) Appl. No.: 13/727,381

(22) Filed: Dec. 26, 2012

Related U.S. Application Data
(60) Provisional application No. 61/587,425, filed on Jan. 17, 2012.

(30) Foreign Application Priority Data
May 18, 2012 (TW) 101117916

(51) Int. Cl. H03K 3/012

(52) U.S. Cl. CPC H03K 3/012
USPC 327/111

(57) ABSTRACT

A timing control circuit for a switching capacitor dynamic switch includes a first time generator and a second time generator. The first generator includes a first capacitor. The first time generator determines a first time by charging to the first capacitor. The second time generator includes a second capacitor. The first time generator is connected to the second time generator. When the first time ends, the second time generator determines a second time by discharging to the second capacitor.

### CROSS-REFERENCE TO RELATED APPLICATIONS

This non-provisional application claims priority under 35 U.S.C. §119(e) on Patent Application No(s). 61/587,425 filed in the United States on Jan. 17, 2012 and under 35 U.S.C. §119(a) on Patent Application No(s). 101117916 filed in Taiwan, R.O.C. on May 18, 2012, the entire contents of which are hereby incorporated by reference.

### TECHNICAL FIELD

The disclosure relates to a timing control circuit for a switching capacitor dynamic switch.

### BACKGROUND

The power management integrated circuit (IC) is widely used in portable electronic devices, such as mobile phone, Personal Digital Assistant (PDA), and laptop. Power management has become more and more important. Generally, a power management IC includes a direct current/direct current (DC/DC) voltage converter which used to provide a stable output voltage by switching the up and down bridge power Metal Oxide Semiconductor (MOS) transistor. However, the output current may generate ripple due to constant switching operations.

There are different control methods for controlling a switch according to different operation modes and requirements. Two common control methods are pulse width modulation (PWM) and pulse frequency modulation (PFM). The former method is to control a switch by adjusting the duty period of the pulse with fixed frequency. The latter method is to fix the opening time or closing time of a switch and change the equivalent duty period by adjusting the frequency of the switch period.

For a DC/DC voltage converter with low power consumption, a DC/DC voltage converter is often designed to work at the discontinuous conduction mode (DCM) due to low average output current. In order to decrease the power consumption, PFM is often used to replace the PWM to decrease the unnecessary switch period. In this way, the switching loss on the whole DC/DC voltage converter could be decreased so as to achieve an improved efficiency and a lower input energy.

When the DC/DC voltage converter works at the discontinuous conduction mode, the inductor current may decrease to zero level through discharge and break to the input or the output, so that the output current is discontinuous. When the inductor current gets to zero level, the inductor current may form a reverse flow because of the inductor current ripple. The energy for the reverse flow is provided by an output capacitor. The current path is from the output to the zero level. Therefore, energy waste will be resulted. Moreover, the opening and closing time is not correct will cause the current to flow through the diode to the output, the conversion efficiency for the DC/DC voltage converter is decreased. To avoid the above problems, a zero current detection circuit is added into the DC/DC voltage converter. When the inductor current is about to form a reverse flow, the zero current detection circuit will quickly inform the system circuit to close the transistor on the path of the reverse flow. As a result, the reverse flow cannot be formed and high conversion efficiency could be maintained. Therefore, how to correctly close the switch has become an important part of control technology.

To achieve a correct switch time, zero current detection circuit is developed. Alternatively, up down bridge switch time could be calculated by using relations between the input voltage and output voltage.

### SUMMARY

In one exemplary embodiment, a timing control circuit for a switching capacitor dynamic switch is disclosed. The timing control circuit comprises a first time generator and a second time generator. The first time generator comprise a first capacitor. The first time generator is configured to determine a first time by charging to the first capacitor. The second time generator is connected to the first time generator. The second time generator is configured to determine a second time by discharging to the second capacitor when the first time ends.

In another exemplary embodiment, a method for a switching capacitor dynamic switch is disclosed. The method comprises charging to a first capacitor in response to a first current, determining a charging state of the first capacitor, generating a divided voltage on an end of a second capacitor, and determining a discharging state of the second capacitor. When a charging voltage of the first capacitor is greater than a first threshold value, the charging process ends. The time from charging to the first capacitor to ending the charging process is defined as a first time. When a discharging voltage of the second capacitor is lower than a second threshold value, the discharging process ends. The time from discharging the second capacitor to ending the discharging process is defined as a second time.

### BRIEF DESCRIPTION OF THE DRAWINGS

The present disclosure will become more fully understood from the detailed description given herein below for illustration only, and thus are not limitative of the present disclosure, and wherein:

FIG. 1 is a timing control circuit for a switching capacitor dynamic switch according to an embodiment of the disclosure;

FIG. 2A to FIG. 2C illustrate operation of a timing control circuit for a switching capacitor dynamic switch according to an embodiment of the disclosure;

FIG. 3 is a timing diagram of a timing control circuit for a switching capacitor dynamic switch according to an embodiment of the disclosure;

FIG. 4 shows a correction circuit according to an embodiment of the disclosure;

and

FIG. 5 shows an approximation circuit in the correction circuit of FIG. 4.

### DETAILED DESCRIPTION

In the following detailed description, for purposes of explanation, numerous specific details are set forth in order to provide a thorough understanding of the disclosed embodiments. It will be apparent, however, that one or more embodiments may be practiced without these specific details. In other instances, well-known structures and devices are schematically shown in order to simplify the drawing.

The detailed characteristics of the disclosure are described in the following embodiments in details, the techniques of the disclosure could be easily understood and embodied by a person of average skill in the art, and the related features of the disclosure could be easily understood by a person of average skill in the art by referring to the contents, the claims and the accompanying drawings disclosed in the specifications.

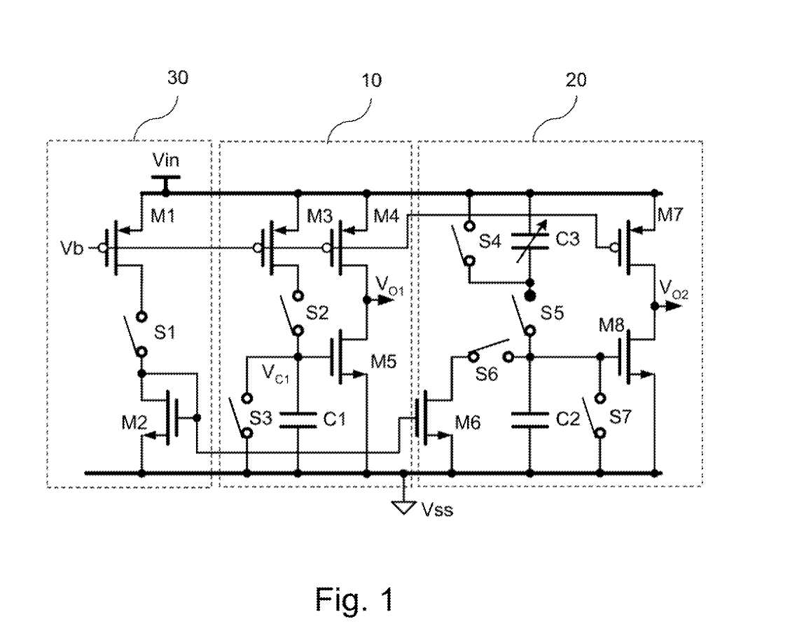

FIG. 1 shows a timing control circuit for a switching capacitor dynamic switch according to an embodiment of the disclosure. For easy illustration, the timing control circuit for a switching capacitor dynamic switch is referred to as the timing control circuit in the following descriptions. The timing control circuit does not use a comparator and an operational amplifier which are energy-consuming in the prior art.

The timing control circuit comprises a first time generator 10 and a second time generator 20. Both the first and second time generators are electrically connected between an electricity power supply voltage Vin and a ground voltage Vss. The typical value of the ground voltage Vss is 0 volt (V). The electricity power supply voltage Vin could also be represented as Vcc which is larger than 0V. Generally, the electricity power supply voltage Vin is 5V.

The first time generator 10 comprises a first current source, a first capacitor C1 connected to the first current source, and a comparator connected between the first current source and the first capacitor C1. The first comparator determines a first time for charging to the first capacitor C1 by the first current source. The second time generator 20 is connected to the first time generator 10. The second time generator 20 comprises a second current source, a second comparator connected between the second current source and the second capacitor C2, and a third capacitor C3 connected to the second capacitor C2. When the first time ends, the second capacitor C2 discharges by the second current source, and the second comparator determines a second time for discharging from the second capacitor C2. The implementation for the first and second comparators, the first current source, and a second current source will be explained in the following descriptions.

In addition, the timing control circuit further comprises an input current source 30 which is connected to the first time generator 10. The first current source in the first time generator 10 and the second current source in the second time generator 20 are current mirrors of the input current source 30. In this embodiment, the input current source is composed of a first transistor M1, a second transistor M2, and a first switch S1 connected between the first transistor M1 and the second transistor M2. The first transistor M1 is a P-channel Metal Oxide Semiconductor (PMOS) transistor and the second transistor M2 is an N-channel Metal Oxide Semiconductor (NMOS) transistor. The source electrode of the first transistor M1 is connected to the electricity power supply voltage Vin, the drain electrode of the first transistor M1 is connected to a first end of the first switch S1, and the gate electrode of the first transistor M1 is connected to a bias voltage Vb. The drain electrode of the second transistor M2 is connected to the second end of the first switch S1, the source electrode of the second transistor M2 is connected to the ground voltage Vss, and the gate electrode of the second transistor M2 is connected to the drain electrode of the second transistor M2. When the first switch is controlled to be closed, a conduction path could be formed. The first and second transistors M1 and M2 could be regarded as the input current source, so that the current mirror circuits in the first time generator 10 and the second time generator 20 could generate a mirror current.

In embodiments of the disclosure, a plurality of switches are used and they are implemented by transistors or logic gates. These switches are controlled by logic circuits to be opened or closed. The switch being closed means that the path where the switch is disposed on is a conduction path, and the switch being open means that the path where the switch is disposed on is a break path.

The following descriptions will illustrate the components and operation of the first time generator 10 and the second time generator 20.

The first time generator 10 comprises the third transistor M3, the fourth transistor M4, the fifth transistor M5, the first capacitor C1, a second switch S2, and a third switch S3. Both the third and fourth transistors M3 and M4 are PMOS transistors, and the fifth transistor is a NMOS transistor. The source electrodes of the third and fourth transistors M3 and M4 are connected to the electricity power supply voltage Vin, and the gate electrodes the two transistors are connected to the bias voltage Vb. The first end of the second switch S2 is connected to the drain electrode of the third transistor M3. The second end of the second switch S2 is connected to the first end of the first capacitor C1.

The second end of the first capacitor C1 is connected to the ground voltage Vss. The drain electrode of the fourth transistor M4 is connected to the drain electrode of the fifth transistor M5. The source electrode of the fifth transistor M5 is connected to the ground voltage Vss. The gate electrode of the fifth transistor M5 is connected between the second end of the second switch S2 and the first end of the first capacitor C1. The first end of the third switch S3 is connected between the second end of the second switch S2 and the first end of the first capacitor C1. The second end of the third switch S3 is connected to the ground voltage Vss.

In the first time generator 10, the third transistor M3 is used to be the first current source. When the second switch S2 is controlled to be closed, the third transistor M3 generates a mirror current to charge to the first capacitor C1 in response to the input current source from the first transistor M1. The fifth transistor M5 is used to be the first comparator which matched with the first capacitor C1 determines the first time. That is, when the electricity quantity of the first capacitor C1 charged by the first current source is greater than the threshold voltage Vth for conducting the fifth transistor M5, the charging time is determined as the first time. When the timing control circuit is used for a DC/DC voltage convertor, the first time refers to the charging time for charging to an inductor or up bridge opening time.

The second time generator 20 comprises the sixth transistor M6, the seventh transistor M7, and the eighth transistor M8, the second capacitor C2, the third capacitor C3, the fourth switch S4, the fifth switch S5, the sixth switch S6, and the seventh switch S7. The sixth and eighth transistors M6 and M8 are NMOS transistors, and the seventh transistor M7 is a PMOS transistor. The gate electrode of the seventh transistor M7 is connected to the bias voltage Vb, the source electrode of the seventh transistor M7 is connected to the electricity power supply voltage Vin, the drain electrode of the seventh transistor M7 is connected to the drain electrode of the eighth transistor M8. The source electrode of the eighth transistor M8 is connected to the ground voltage Vss. The gate electrode of the eighth transistor M8 is connected to the first end of the sixth switch S6 and the first end of the seventh switch M7. The second end of the seventh switch S7 is connected to the ground voltage Vss. The second end of the fifth switch S5 is connected to the drain electrode of the sixth transistor M6. The source electrode of the sixth transistor M6 is connected to the ground voltage Vss, and the gate electrode of the sixth transistor M6 is connected to the gate electrode of the second transistor M2.

The third capacitor C3 is connected in parallel with the fourth switch S4. The first end of the third capacitor C3 and the first end of the fourth switch S4 are connected to the electricity power supply voltage Vin. The second end of the third capacitor C3 is connected to the second end of the fourth switch S4 and the first end of the fifth switch S5. The second end of the fifth switch S5 is connected to the first end of the second capacitor C2. The second end of the second capacitor C2 is connected to the ground voltage Vss.

In the second time generator 20, the sixth transistor M6 is used as the second current source. The eighth transistor M8 is used to the second comparator which matched with the second and third capacitors C2 and C3 determines the second time. When the timing control circuit is used in a DC/DC voltage converter, the second time refers to the discharging time for discharging from an inductor or down bridge opening time.

In embodiments of the disclosure, a fixed current source is used [symbol] to charge to a capacitor. The voltage of the capacitor is discharge to the threshold voltage of a transistor. Furthermore, the fifth and eighth transistors are used as comparators .when the timing control circuit is used in a DC/DC voltage converter and the inductor in the DC/DC voltage converter is being charged, the first current source will charge to the first capacitor C1. The charging period Ton could be obtained by the following equation (1).

$${T}_{ON} = \frac{{V}_{th ( M 5 )} \cdot C 1}{{I}_{C}} \qquad ( 1 )$$

After the charging period is achieved by controlling current and capacitors, the second capacitor C2 and the third capacitor C3 of the second time generator control the discharging time after the charging period ends. The divided voltageVc₂ is obtained by the following equation (2):

$${V}_{C 2} = \frac{α}{1 + α} {V}_{in} where α = \frac{{C}_{2}}{{C}_{3}} \qquad ( 2 )$$

Based on the divided voltageVc₂, the voltage Vin at the sample input end, the voltage on the discharging capacitor C2, the discharging period Toff for discharging from the inductor could be obtained by the following equation (3).

$${T}_{OFF} = \frac{( \frac{α}{1 + α} \cdot {V}_{in} - {V}_{th ( M 8 )} )}{{I}_{c}} \cdot {C}_{2} \qquad ( 3 )$$

Based on the equations (1)-(3), input and output voltages, a balance equation under a discontinuous conduction mode for steady state inductor's charging and discharging time could be obtained. The divided voltage could be adjusted by adjusting the parameter α. As a result, a correct discharging time could be generated to match with the charging time according to different input and output voltages. Therefore, a zero current switch consuming low energy is achieved.

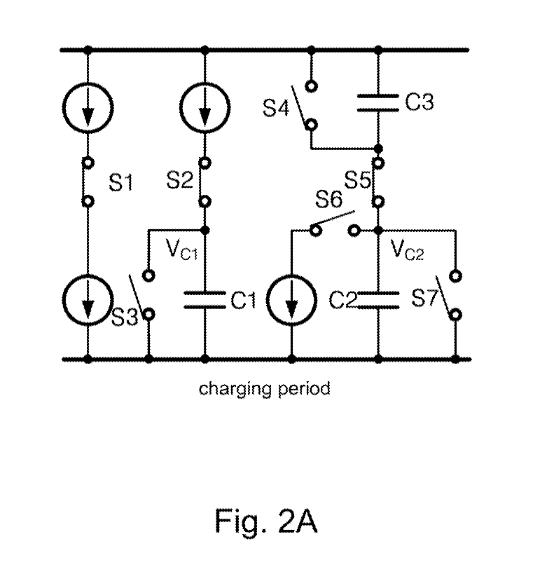

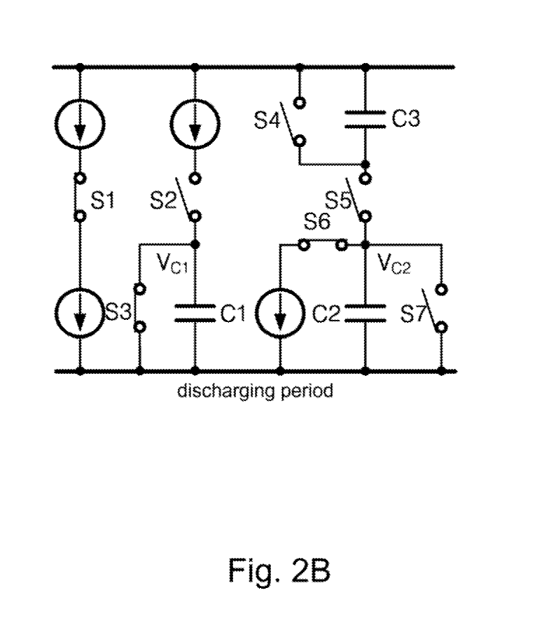

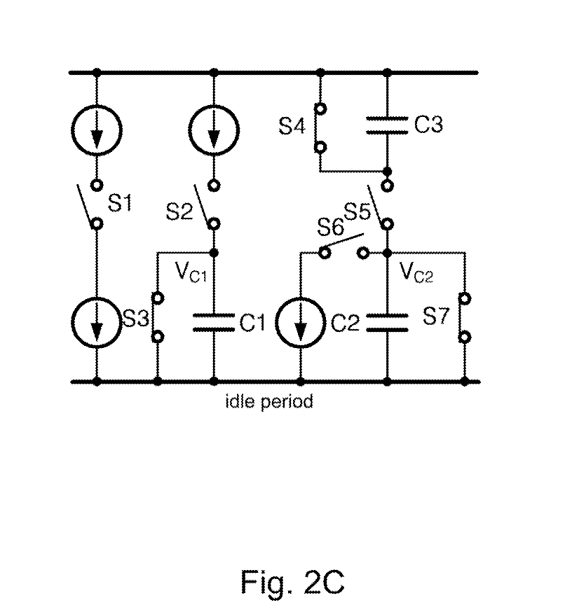

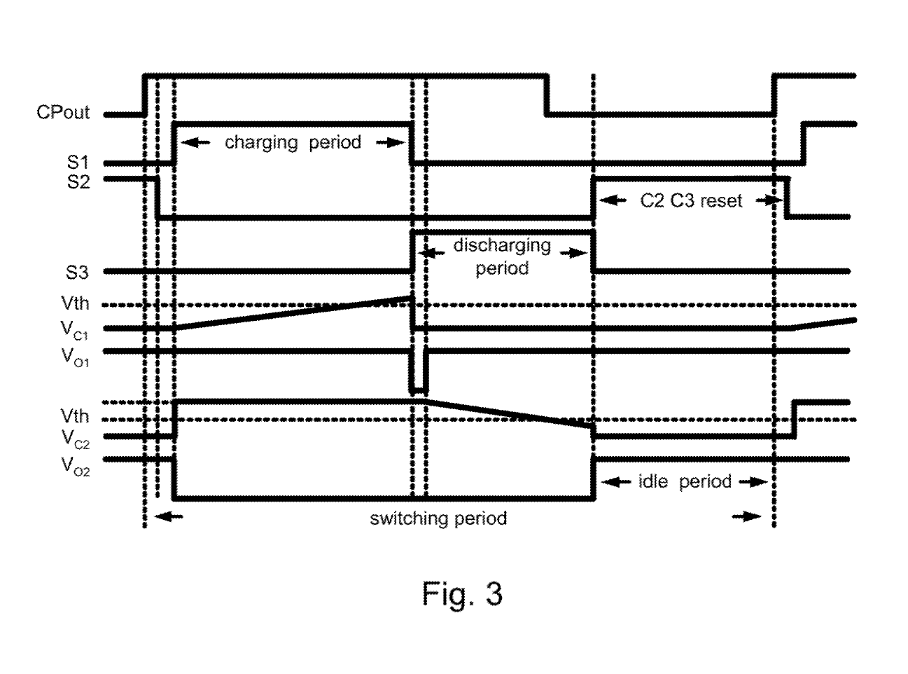

The operation process of the timing control circuit will be explained below with reference to FIGS. 2A, 2B, 2C, and 3.

The signal CPout is a control signal for controlling the timing control circuit. When the timing control circuit is used in a DC/DC voltage converter, the control signal CPout may come from the comparator.

In the timing control circuit, there are seven switches, i.e., the first switch S1 to the seventh switch S7. The second switch S2 and the fifth switch S5 will be open or closed at the same time. The third switch S3, the fourth switch S4, and the seventh switch S7 will be open or disclosed at the same time. The state of opening or closing the first switch S1 is opposite to the state of the third, fourth, and seventh switches S3, S4, and S7. That is, if the third, fourth, and seventh switches S3, S4, and S7 are open, the first switch is closed. In this case, an inverter (not shown in FIGS. 2A-2C) is disposed to connect to the first switch S1 so that the same logic control signal could be used to control the states of the first, third, fourth, and seventh switches S1, S3, S4, and S7.

As shown in FIG. 2A, when the first switch S1 is closed, the third transistor M3 is used as a current source. The first capacitor C1 will be charged. As shown in FIG. 3, the voltage Vc₁ of the first capacitor C1 increases gradually. In this period, the third, fourth, and seventh switches S3, S4, and S 7 are open. The voltage of the second capacitor C2 maintains at the saturate state. When the voltage of the first capacitor C1 is greater than the threshold voltage Vₜₕ for conducting the fifth transistor M5, the second switch S2 will be open to form a break circuit. At this time, the charging period for the first capacitor C1ends and the discharging period begins.

In the discharging period, the second switch S2 and the fifth switch S5 are open and the current source will not charge to the first capacitor C1. The first capacitor C1 begins to discharge. At this time, the third, fourth, and seventh switches S3, S4, and S7 are still open. The sixth switch S6 is closed so that the second capacitor C2 discharges. When the voltage of the second capacitor C2 is lower than the threshold voltage Vₜₕ for conducting the eighth transistor, the discharging period ends and the idle period begins.

In the idle period, the second, fifth, and sixth switches S2, S5, and S6 are open. The third, fourth, and seventh switches S3, S4, and S7 are closed. In this period, the second and third capacitors C2 and C3 will finish discharging.

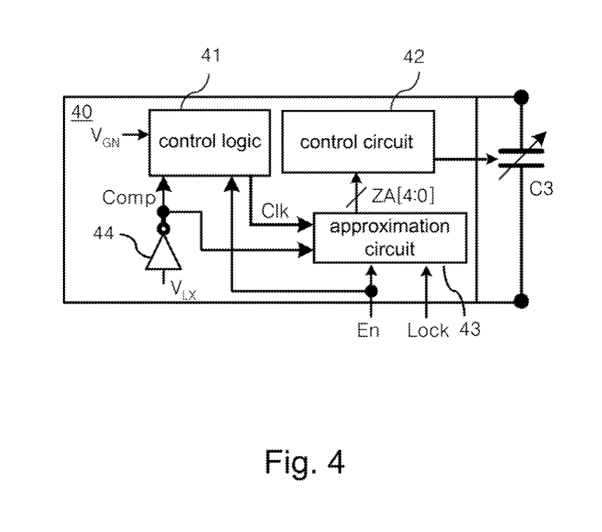

When the timing control circuit is used in a DC/DC voltage converter, the analog integrated circuit may be influenced by the mismatching of components or delay time of system circuit. Different zero current switch points will cause different discharging states of the inductor in the DC/DC voltage converter. If the inductor current is not discharged completely or is discharged excessively, the voltage of the inductor will be changed. Therefore, based on this voltage change, a circuit such as inverter, comparator, or amplifier could be used to detect the voltage. After the voltage detection, the capacitance value of the third capacitor C3 is adjusted to adjust the divided voltage ratio. Therefore, an assistant process or delay variation for discharging time value is generated to revise the incorrect discharging time. The power consumption efficiency of the system could be improved. With reference to FIG. 4, the timing control circuit further comprises a correction circuit 40 which is connected to the third capacitor. The correct circuit 40 is used to revise the incorrect discharging time for an inductor which is caused by process variation and delay. In particular, the correction circuit 40 is used to change the capacitance value of the third capacitor so as to decrease the undesired error. That is, the discharging time could be revised by changing the capacitance value of the third capacitor. Therefore, the capacitance value of the third capacitor C3 could be adjusted in an embodiment.

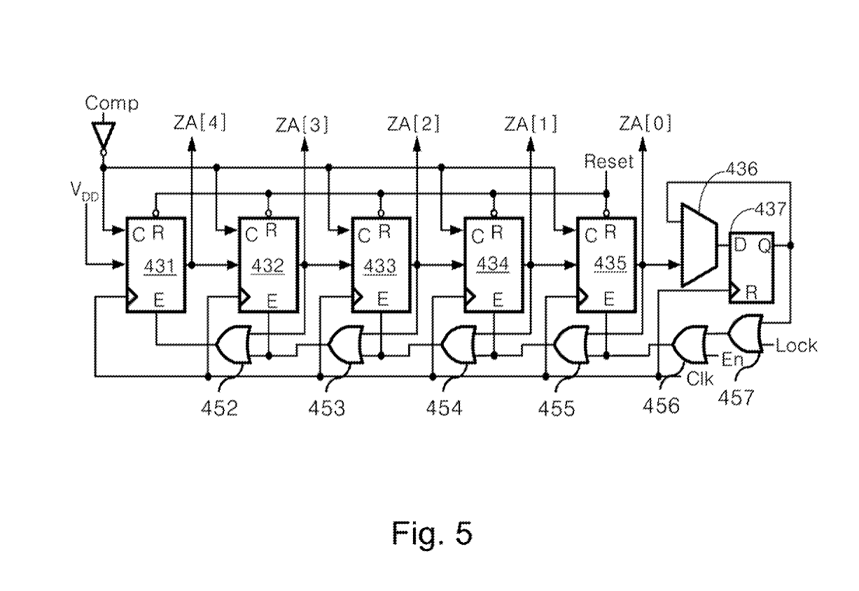

In an embodiment, the correction circuit 40 may be implemented by a five-bit successive approximation register. The correction circuit 40 of FIG. 4 comprises a control logic 41, a control circuit 42, and an approximation circuit 43. The control logic 41 is controlled by the external voltage V_{GN} and outputs the frequency signal C1k to the approximation circuit 43. Furthermore, the control logic 41 is controlled by an enable signal En. The control circuit 42 determines whether to increase or decrease the capacitance value of the third capacitor C3 in response to the output from the approximation circuit 43. The approximation circuit 43 of FIG. 5 is a five-bit successive approximation register. The approximation circuit 43 comprises five caches 431-435, a multiplexer 436, and a D-type flip-flop 437. Each of the caches 432-435 is configured with a logic gate 452-455. Furthermore, the approximation circuit 43 comprises logic gates 456 and 457. All the logic gates in FIG. 5 are OR gates. With reference to FIG. 4, the inverter 44 used as a sensor generates a conversion signal Comp which represents a too long or too short zero current diction (ZCD). The conversion signal Comp is stored in each of the caches 431-435. The Most Significant Bit (MSB) ZA (4) is set as high voltage level (i.e., the logic value is 1) so as to facilitate the correction process. The conversion signal Comp outputted from the inverter 44 is determined by an external voltage V_{LX}. If the voltage of V_{LX} is at low level, the conversion signal Comp will be inverted to be at high level and is outputted to the approximation circuit 43 so as to increase the capacitance value of the third capacitor C3. The V_{LX}at low level means a too short closing time. On the other hand, if the voltage of V_{LX} is at high level, the conversion signal Comp will be inverted to be at low level and is outputted to the approximation circuit 43 so as to decrease the capacitance value of the third capacitor C3. The V_{LX} at high level means a too long closing time. After the comparison performed by the cache at work, the next cache will be triggered to set the signal ZA[n-1] as the high logic level 1 so as to perform the next comparison. At the same time, the approximation circuit 43 receives the conversion signal Comp to determine whether to set the output signal ZA[n] to be 0 or 1. After five comparisons, the level of the Least Significant Bit (LSB) could be determined. The D-type flip-flop 437 will be set as high level and be locked at the high level. At this time, the state of the approximation circuit 43 will be maintained to output a correct closing time. In addition, a lock signal from the external circuit will lock the approximation circuit 43 or make the LSB continue to work.

In another embodiment, the correction circuit may be implemented by a mountain climbing method or an up down counter.

The timing control circuit for a switching capacitor dynamic switch of the disclosure is mainly composed of a set of switching capacitor circuits and control logic circuits. A very low power is consumed. The present disclosure does not need an amplifier or a comparator to lock or judge the voltage signal. Instead, a transistor for controlling a current source is used as a comparator. As a result, a switch signal for balancing up bridge and down bridge is achieved. The inductor current could be correctly discharged to be zero level and the DC/DC converter could be work at the discontinuous conduction mode with high efficiency. In addition, in the idle period, the timing control circuit is completely closed and no energy is consumed. When the timing control circuit is open, the control current makes the timing control circuit work at a very low current level.

It should be noted that although the timing control circuit of the disclosure aims to save the power consumption of the DC/DC voltage converter and zero current control problems, it is not intended to limit the disclosure to be used for merely the DC/DC voltage converter. The disclosure could be applied in any circuit which needs to control charging and discharging.

Note that the specifications relating to the above embodiments should be construed as exemplary rather than as limitative of the present disclosure, with many variations and modifications being readily attainable by a person skilled in the art without departing from the spirit or scope thereof as defined by the appended claims and their legal equivalents.

What is claimed is:

1. A timing control circuit for a switching capacitor dynamic switch, comprising:
a first time generator comprising a first capacitor, the first time generator being configured to determine a first time by charging to the first capacitor; and
a second time generator comprising a second capacitor, the second time generator being connected to the first time generator, the second time generator being configured to determine a second time by discharging to the second capacitor when the first time ends.

2. The timing control circuit according to claim 1, wherein the first time generator further comprises a first current source and a first comparator, the first capacitor being connected to the first current source, the first comparator being connected between the first current source and the first capacitor, wherein the first comparator is configured to determine the first time for charging to the first capacitor from the first current source.

3. The timing control circuit according to claim 2, wherein the second time generator further comprises a second current source and a second comparator, the second capacitor being connected to the second current source, the second comparator being connected to the second capacitor, wherein when the first time ends, the second capacitor is configured to discharge to the second current source, and the second comparator is configured to determine the second time for discharging from the second capacitor.

4. The timing control circuit according to claim 3, further comprising a third capacitor connected to the second capacitor.

5. The timing control circuit according to claim 4, further comprising a correction circuit connected to the third capacitor, the correction circuit being configured to change a capacitance value of the third capacitor to revise discharging time.

6. The timing control circuit according to claim 3, further comprising an input current source connected to the first time generator, wherein the first current source and the second current source generate mirror current of the input current source.

7. The timing control circuit according to claim 6, wherein the input current source comprises a first transistor, a second transistor, and a first switch connected between the first transistor and the second transistor.

8. The timing control circuit according to claim 7, wherein the first current source in the first time generator is a third transistor.

9. The timing control circuit according to claim 8, wherein the first time generator further comprising:
a second switch connected between the second transistor and the first capacitor;
a third switch connected in parallel with the first capacitor and connected in serial with the second switch; and
a fourth transistor connected to the third transistor.

10. The timing control circuit according to claim 9, wherein the first comparator is a fifth transistor connected to the fourth transistor.

11. The timing control circuit according to claim 4, wherein the second current source in the second time generator is a sixth transistor.

12. The timing control circuit according to claim 11, wherein the second time generator further comprising:
a fourth switch connected to the third capacitor;
a fifth switch connected between the second capacitor and the third capacitor;
a sixth switch connected between the sixth transistor and the second capacitor;
a seventh switch connected to the second capacitor; and
a seventh transistor connected the third capacitor and the second comparator.

13. The timing control circuit according to claim 12, wherein the second comparator is an eighth transistor connected to the seventh transistor.

14. A method for controlling a timing control circuit for a switching capacitor dynamic switch, comprising:
charging to a first capacitor in response to a first current;
determining a charging state of the first capacitor, when a charging voltage of the first capacitor is greater than a first threshold value, a charging process ends, and time from charging to the first capacitor to ending the charging process is defined as a first time;
generating a divided voltage on an end of a second capacitor, the second capacitor discharges in response to a second current; and
determining a discharging state of the second capacitor, when a discharging voltage of the second capacitor is lower than a second threshold value, a discharging process ends, and time from discharging to the second capacitor to ending the discharging process is defined as a second time.

15. The method according to claim 14, further comprising providing an input current so that a first current source generates the first current in response to the input current and a second current source generates the second current in response to the input current, wherein the first current and the second current are mirror current of the input current.

16. The method according to claim 14, further comprising a correction step for changing a capacitance value of a third capacitor connected to the second capacitor to correct discharging time.
